(19) United States
(12) Patent Application Publication
(10) Pub. No.: US 2026/0149270 A1
(43) Pub. Date: May 28, 2026

(54) ELECTROSTATIC DISCHARGE PROTECTION CIRCUIT

(71) Applicant: RichWave Technology Corp., Taipei (TW)

(72) Inventors: Ching-Yao Pai, Taipei (TW); Yi Hsiang Huang, Taipei (TW)

(73) Assignee: RichWave Technology Corp., Taipei (TW)

(21) Appl. No.: 18/988,909

(22) Filed: Dec. 20, 2024

(30) Foreign Application Priority Data
Nov. 28, 2024 (TW) 113145975

(51) Int. Cl. H02H 9/04

(52) U.S. Cl. CPC H02H 9/046

(57) ABSTRACT

An electrostatic discharge (ESD) protection circuit is coupled between first and second voltage terminals, and further includes first and second bipolar junction transistors (BJTs). First terminals of the first and second BJTs are coupled to the first voltage terminal and the second voltage terminal respectively. Second terminals of the first and second BJTs are coupled to each other. Control terminals of the first and second BJTs are coupled to each other. A breakdown voltage of a junction between the first terminal and the control terminal of the first BJT is greater than a breakdown voltage of a junction between the second terminal and the control terminal of the first BJT. A breakdown voltage of a junction between the first terminal and the control terminal of the first BJT is greater than a breakdown voltage of a junction between the second terminal and the control terminal of the first BJT.

### CROSS-REFERENCE TO RELATED APPLICATION

This application claims the priority benefit of Taiwan application serial no. 113145975, filed on Nov. 28, 2024. The entirety of the above-mentioned patent application is hereby incorporated by reference herein and made a part of this specification.

### BACKGROUND

### Technical Field

The disclosure relates to a circuit design technology, and in particular to an electrostatic discharge (ESD) protection circuit.

### Description of Related Art

The electrostatic discharge (ESD) protection circuit is mainly used to prevent problems, such as damage to the circuit system, caused by the current generated when an electrostatic discharge event occurs, such as human body model (HBM), system-level electrostatic discharge, and surge pulses. Electrostatic discharge protection circuit is widely used in various integrated circuits. In response to different technical application scenarios, the electrostatic discharge protection circuit may be implemented using different types of transistors and diverse circuit structures.

### SUMMARY

The disclosure provides an electrostatic discharge protection (ESD) circuit that increases the overall anti-interference ability of the electrostatic discharge circuit through the base-collector junction in the hetero-bipolar junction transistor.

The electrostatic discharge protection circuit of the embodiment of the disclosure is coupled between a first voltage terminal and a second voltage terminal. The electrostatic discharge protection circuit includes a first bipolar junction transistor (BJT) and a second bipolar junction transistor. The first bipolar junction transistor has a first terminal, a second terminal, and a control terminal, and the first terminal of the first bipolar junction transistor is coupled to the first voltage terminal. The second bipolar junction transistor has a first terminal, a second terminal, and a control terminal, the second terminal of the second bipolar junction transistor is coupled to the second terminal of the first bipolar junction transistor, the first terminal of the second bipolar junction transistor is coupled to the second voltage terminal, and the control terminal of the first bipolar junction transistor is coupled to the control terminal of the second bipolar junction transistor. A first breakdown voltage of a first junction between the first terminal and the control terminal of the first bipolar junction transistor is greater than a second breakdown voltage of a second junction between the second terminal and the control terminal of the first bipolar junction transistor. Moreover, a third breakdown voltage of a third junction between the first terminal and the control terminal of the second bipolar junction transistor is greater than a fourth breakdown voltage of a fourth junction between the second terminal and the control terminal of the second bipolar junction transistor.

The electrostatic discharge protection circuit of the embodiment of the disclosure is coupled between a first voltage terminal and a second voltage terminal. The electrostatic discharge protection circuit includes a first bipolar junction transistor (BJT) and a second bipolar junction transistor. The first bipolar junction transistor has a first terminal, a second terminal, and a control terminal, and the first terminal of the first bipolar junction transistor is coupled to the first voltage terminal. The second bipolar junction transistor has a first terminal, a second terminal, and a control terminal, the second terminal of the second bipolar junction transistor is coupled to the second terminal of the first bipolar junction transistor, the first terminal of the second bipolar junction transistor is coupled to the second voltage terminal, and the control terminal of the first bipolar junction transistor is coupled to the control terminal of the second bipolar junction transistor. A first doping concentration of the semiconductor material forming the first terminal of the first bipolar junction transistor is lower than a second doping concentration of the semiconductor material forming the second terminal of the first bipolar junction transistor, and a third doping concentration of the semiconductor material forming the first terminal of the second bipolar junction transistor is lower than a fourth doping concentration of the semiconductor material forming the second terminal of the second bipolar junction transistor.

Based on the above, through a specific circuit structure, the electrostatic discharge protection circuit of the embodiments of the disclosure utilizes the base-collector junction of the hetero-bipolar junction transistor to be coupled to the corresponding voltage terminal, instead of utilizing the base-emitter junction with a lower breakdown voltage to be coupled to the voltage terminal. Therefore, when a voltage electrostatic discharge event occurs, the electrostatic discharge protection circuit can increase the anti-interference ability based on the base-collector junction with a relatively high breakdown voltage.

### BRIEF DESCRIPTION OF THE DRAWINGS

FIG. 1 is a schematic diagram of an electrostatic discharge protection circuit according to an embodiment of the disclosure.

FIG. 2A to FIG. 2H are respectively schematic circuit diagrams of electrostatic discharge protection circuits according to the first embodiment to the eighth embodiment of the disclosure.

FIG. 3 is a schematic circuit diagram of an impedance circuit according to various embodiments of the disclosure.

FIG. 4A to FIG. 4B are respectively schematic circuit diagrams of electrostatic discharge protection circuits according to the ninth embodiment to the tenth embodiment of the disclosure.

FIG. 5A to FIG. 5G are respectively schematic circuit diagrams of electrostatic discharge protection circuits according to the eleventh embodiment to the seventeenth embodiment of the disclosure.

### DESCRIPTION OF THE EMBODIMENTS

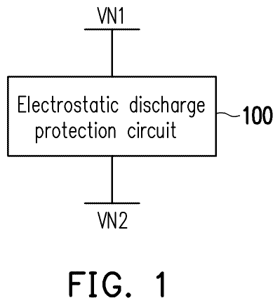

FIG. 1 is a schematic diagram of an electrostatic discharge (ESD) protection circuit 100 according to an embodiment of the disclosure. The electrostatic discharge protection circuit 100 is coupled between voltage terminals VN1 and VN2. The electrostatic discharge protection circuit 100 may be disposed at the input terminal or output terminal of an electronic circuit (for example, a high-power radio frequency signal processing circuit). The high-power radio frequency signal processing circuit is, for example, an amplifier circuit. The voltage terminal VN1 is used to input radio frequency signals, and the power of the radio frequency signal may be greater than or equal to 30 dBm.

Under normal operating voltage conditions, the electrostatic discharge protection circuit 100 does not affect the operation of the electronic circuit. On the other hand, when a surge occurs at either voltage terminal VN1 or VN2 due to electrostatic discharge, the electrostatic discharge protection circuit 100 may direct the surge to the other voltage terminal VN1 or VN2, thereby protecting the input terminal or the output terminal of the electronic circuit from the impact of the surge. It is assumed here that the voltage value at the voltage terminal VN1 is higher than the voltage value at the voltage terminal VN2.

Although the electrostatic discharge protection circuit may be implemented using a single hetero-bipolar junction transistor (HBT), the emitter in the HBT has a dense, highly-doped semiconductor material and is more prone to electrical conductivity. As a result, the base-emitter junction in the HBT has a lower breakdown voltage. Therefore, when a positive/negative voltage electrostatic discharge event occurs, that is, when the voltage value at the voltage terminal VN1 is higher/lower than the voltage value at the voltage terminal VN2 for a certain period of time, the base-emitter junction in the HBT is more likely to turn on due to the lower breakdown voltage thereof, as a result, which leads to poor anti-interference ability of the electrostatic discharge protection circuit during the positive/negative voltage electrostatic discharge event. In order for the electrostatic discharge protection circuit to have better anti-interference ability, a larger circuit layout area is required to set up the HBT in the electrostatic discharge protection circuit.

Through a specific circuit structure, an embodiment of the disclosure utilizes the base-collector junction of the hetero-bipolar junction transistor to be coupled to the corresponding voltage terminals VN1 and VN2. Therefore, when the positive/negative voltage electrostatic discharge event occurs, the electrostatic discharge protection circuit can increase the anti-interference ability by using the base-collector junction with a relatively high breakdown voltage.

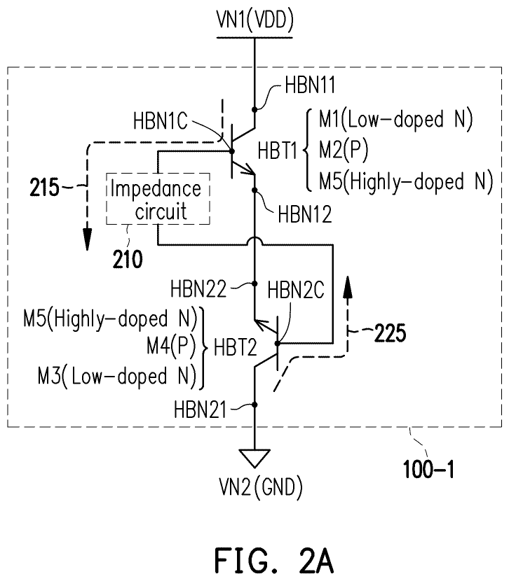

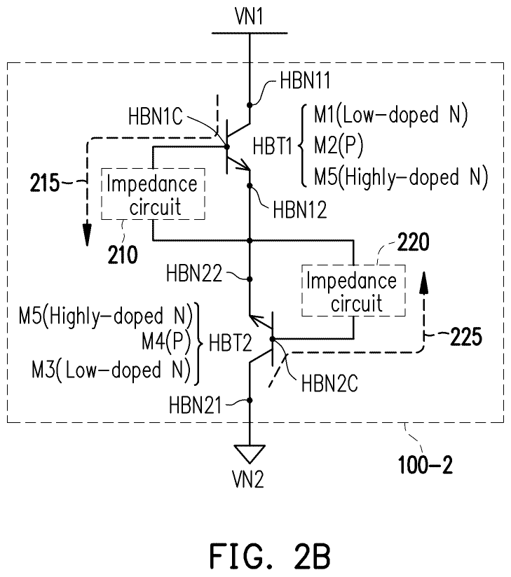

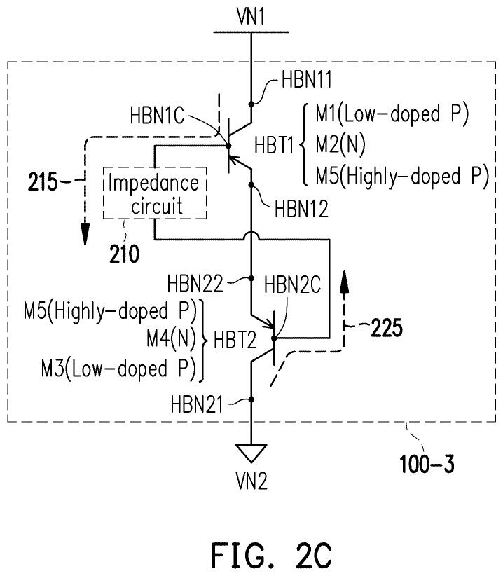

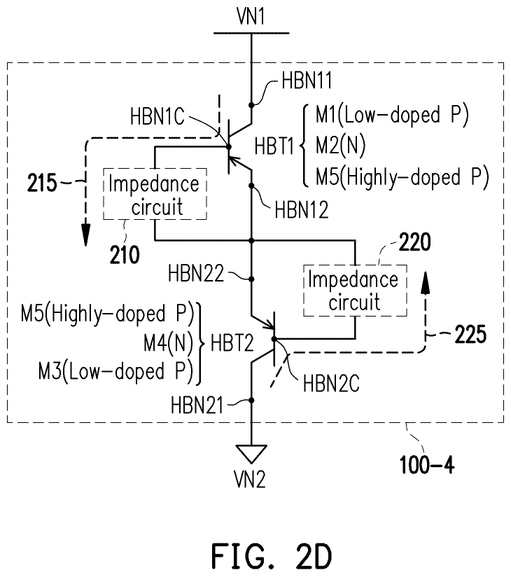

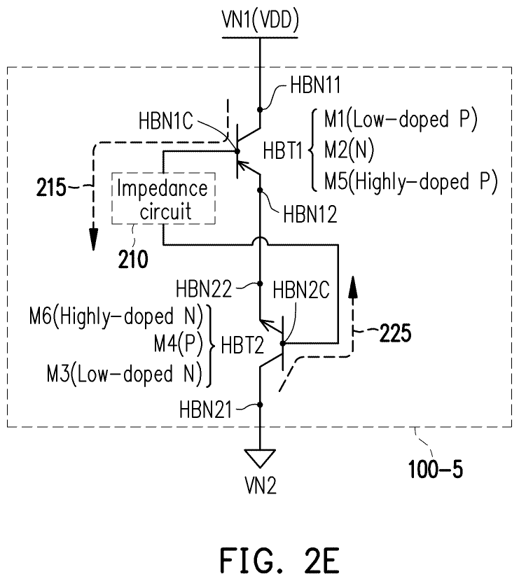

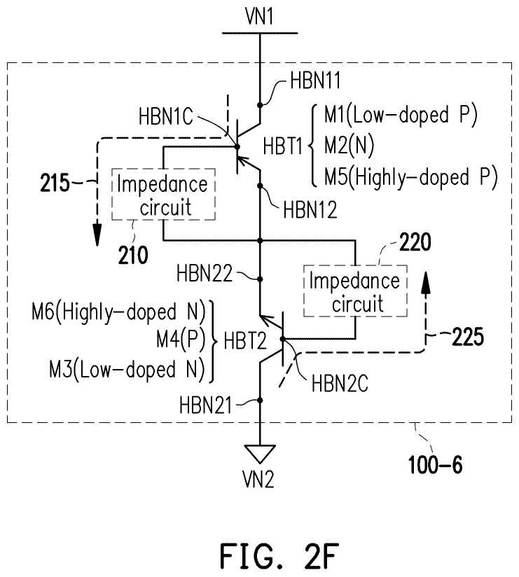

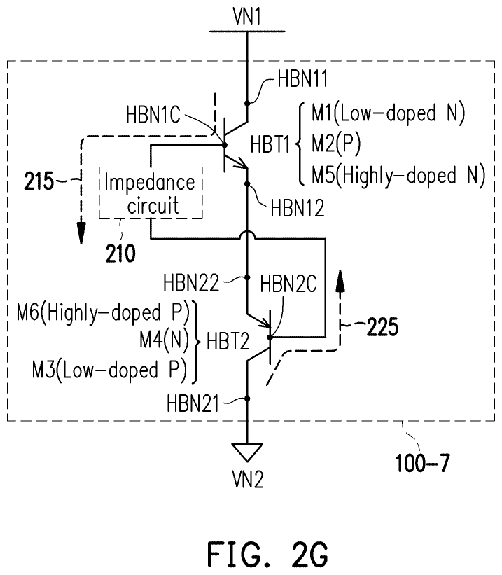

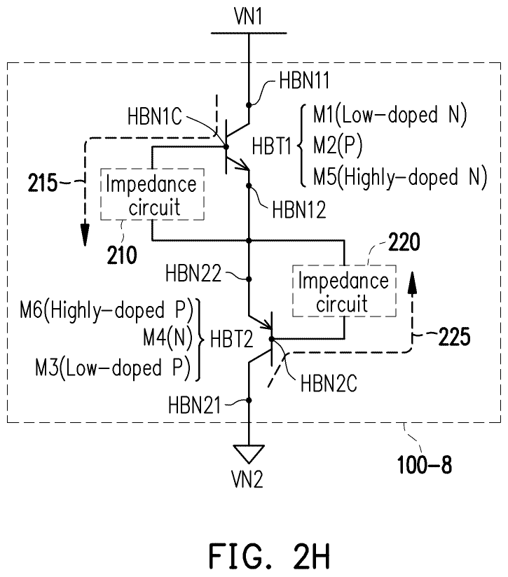

FIG. 2A to FIG. 2H are respectively schematic circuit diagrams of electrostatic discharge protection circuits 100-1 to 100-8 according to the first embodiment to the eighth embodiment of the disclosure. The electrostatic discharge protection circuit 100-1 in FIG. 2A is coupled between the voltage terminal VN1 and the voltage terminal VN2. The voltage terminal VN1 of this embodiment takes a voltage input terminal VDD as an example. The voltage value of the voltage terminal VN1 may be a positive value or a negative value, and the voltage terminal VN2 takes a reference voltage terminal GND as an example. Implementers of this embodiment may adjust the voltage values at the voltage terminal VN1 and the voltage terminal VN2 according to the needs.

The electrostatic discharge protection circuit 100-1 in FIG. 2A includes bipolar junction transistors HBT1 and HBT2 (hereinafter referred to as transistors HBT1 and HBT2). The transistors HBT1 and HBT2 are disposed on the same integrated circuit substrate. The transistors HBT1 and HBT2 in this embodiment are implemented using hetero-bipolar junction transistor (HBT). The materials of the transistors HBT1 and HBT2 may include, for example, silicon germanium, gallium arsenide, or silicon. The transistor HBT1 has a terminal HBN11 (for example, collector terminal), a terminal HBN12 (for example, emitter terminal), and a control terminal HBN1C (for example, base terminal). The terminal HBN11 of the transistor HBT1 is coupled to the voltage terminal VN1.

The transistor HBT2 has a terminal HBN21 (for example, collector terminal), a terminal HBN22 (for example, emitter terminal), and a control terminal HBN2C (for example, base terminal). The terminal HBN22 (for example, the emitter terminal) of the transistor HBT2 is coupled to the terminal HBN12 (for example, the emitter terminal) of the transistor HBT1. The terminal HBN21 of the transistor HBT2 is coupled to the voltage terminal VN2. The control terminal HBN1C of the transistor HBT1 is coupled to the control terminal HBN2C of the transistor HBT2.

In this embodiment, the breakdown voltage of the junction (referred to as a first junction) between the terminal HBN11 and the control terminal HBN1C of the transistor HBT1 is greater than the breakdown voltage of the junction (referred to as a second junction) between the terminal HBN12 and the control terminal HBN1C of the transistor HBT1. Moreover, the breakdown voltage of the junction (referred to as a third junction) between the terminal HBN21 and the control terminal HBN2C of the transistor HBT2 is greater than the breakdown voltage of the junction (referred to as a fourth junction) between the terminal HBN22 and the control terminal HBN2C of the transistor HBT2.

In FIG. 2A, the transistors HBT1 and HBT2 are NPN-type heterojunction bipolar transistors. The terminal HBN11 of the transistor HBT1 in FIG. 2A is formed of a semiconductor material M1, and the control terminal HBN1C of the transistor HBT1 is formed of a semiconductor material M2. The terminal HBN21 of the transistor HBT2 is formed of a semiconductor material M3, and the control terminal HBN2C of the transistor HBT2 is formed of a semiconductor material M4. The terminal HBN12 of the transistor HBT1 and the terminal HBN22 of the transistor HBT2 are both formed of a semiconductor material M5.

In FIG. 2A, the semiconductor materials M1, M3, and M5 have the same electrical conductivity type, for example, N-type electrical conductivity type or P-type electrical conductivity type. The semiconductor materials M2 and M4 have the same electrical conductivity type, but have different electrical conductivity types from the semiconductor materials M1, M3, and M5. That is to say, as in the embodiment of FIG. 2A, the semiconductor materials M1, M3, and M5 are N-type conductive type semiconductor materials, while the semiconductor materials M2 and M4 are P-type conductive type semiconductor materials. On the other hand, in FIG. 2C of a similar embodiment described later, the semiconductor materials M1, M3, and M5 are P-type conductive type semiconductor materials, while the semiconductor materials M2 and M4 are N-type conductive type semiconductor materials.

The transistors HBT1 and HBT2 in this embodiment are implemented by hetero-bipolar junction transistors. Therefore, the semiconductor material M5 is different from the semiconductor material M1 or the semiconductor material M3.

In FIG. 2A, the semiconductor materials M1 and M3 are each low-doped N-type semiconductor materials, the semiconductor materials M2 and M4 are each P-type semiconductor materials, and the semiconductor material M5 is a highly-doped N-type semiconductor material. Therefore, the situation in which the breakdown voltage of the first junction in the transistor HBT1 is greater than the breakdown voltage of the second junction in the transistor HBT1, and the breakdown voltage of the third junction in the transistor HBT2 is greater than the breakdown voltage of the fourth junction in the transistor HBT2, may be implemented. In other words, the doping concentration of the semiconductor material M1 forming the terminal HBN11 of the transistor HBT1 is lower than the doping concentration of the semiconductor material M5 forming the terminal HBN12 of the transistor HBT1, and the doping concentration of the semiconductor material M3 forming the terminal HBN21 of the transistor HBT2 is lower than the doping concentration of the semiconductor material M5 forming the terminal HBN22 of the transistor HBT2. The doping concentration of the semiconductor material M1 is, for example, equal to the doping concentration of the semiconductor material M3.

In this embodiment, both transistors HBT1 and HBT2 are designed as the same NPN-type or PNP-type heterojunction bipolar transistor. Therefore, the breakdown voltage of the first junction is equal to the breakdown voltage of the third junction, and the breakdown voltage of the second junction is equal to the breakdown voltage of the fourth junction.

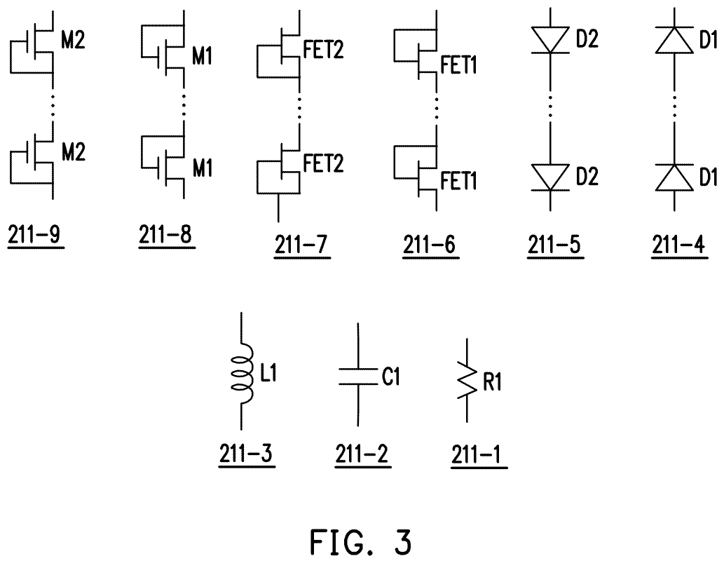

The electrostatic discharge protection circuit 100-1 in FIG. 2A further includes an impedance circuit 210. The impedance circuit 210 is coupled between the control terminal HBN1C of the transistor HBT1 and the control terminal HBN2C of the transistor HBT2. For the detailed circuit structure of the impedance circuit 210, reference may be made to the following FIG. 3 and the description of the corresponding embodiment.

The impedance circuit 210 may provide a bias voltage to conduct the transistor HBT1 and the transistor HBT2 when an electrostatic discharge event occurs, thereby causing the transistor HBT1 and the transistor HBT2 to discharge the electrostatic discharge current. In this embodiment, the product of the impedance value of the impedance circuit 210 and the breakdown current of the first junction in the transistor HBT1 is greater than or equal to the conduction voltage of the second junction in the transistor HBT1. Referring to FIG. 2A, when the voltage value of the voltage terminal VN1 is greater than the voltage value of the voltage terminal VN2, and the voltage difference between the voltage terminal VN1 and the voltage terminal VN2 is greater than the breakdown voltage of the first junction in the transistor HBT1 (the junction between the terminal HBN11 and the control terminal HBN1C), the electrostatic discharge event occurs. At this time, since the terminal HBN11 of the transistor HBT1 is formed of a low-doped semiconductor material, the breakdown voltage of the first junction of the transistor HBT1 is relatively high, which results in relatively high anti-interference ability. Therefore, the first junction of the transistor HBT1 is not damaged, and generates breakdown current. The breakdown current may flow through the impedance circuit 210 along the path direction indicated by the dashed line arrow 215 shown in FIG. 2A. When the product of the impedance value of the impedance circuit 210 and the breakdown current of the first junction in the transistor HBT1 is greater than the conduction voltage of the second junction (the junction between the terminal HBN12 and the control terminal HBN1C) in the transistor HBT1, the transistor HBT1 may be turned on, and the breakdown current may turn the transistor HBT2 on, forming an electrostatic discharge current discharge path. In this way, the electrostatic discharge current may be directed from the voltage terminal VN1 to the voltage terminal VN2 through the transistor HBT1 and the transistor HBT2. On the other hand, when the voltage value of the voltage terminal VN1 is lower than the voltage value of the voltage terminal VN2, and the voltage difference between the voltage terminal VN1 and the voltage terminal VN2 is greater than the breakdown voltage of the third junction in the transistor HBT2 (the junction between the terminal HBN21 and the control terminal HBN2C), the electrostatic discharge event occurs. At this time, since the terminal HBN21 of the transistor HBT2 is formed of a low-doped semiconductor material, the breakdown voltage of the third junction in the transistor HBT2 is relatively high, which results in relatively high anti-interference ability. Therefore, the third junction of the transistor HBT2 is not damaged, and generates breakdown current. The breakdown current may flow through the impedance circuit 210 along the path direction indicated by the dashed line arrow 225 shown in FIG. 2A. When the product of the impedance value of the impedance circuit 210 and the breakdown current of the third junction in the transistor HBT2 is greater than the conduction voltage of the fourth junction (the junction between the terminal HBN22 and the control terminal HBN1C) in the transistor HBT2, the transistor HBT2 may be turned on, and the breakdown current may turn the transistor HBT1 on to form an electrostatic discharge current discharge path. In this way, the electrostatic discharge current may be directed from the voltage terminal VN2 to the voltage terminal VN1 through the transistor HBT2 and the transistor HBT1.

The transistors HBT1 and HBT2 in FIG. 2A and FIG. 2B are both NPN-type heterojunction bipolar transistors. The difference between an electrostatic discharge protection circuit 100-2 in FIG. 2B and the electrostatic discharge protection circuit 100-1 in FIG. 2A is that, in the electrostatic discharge protection circuit 100-2, the terminal HBN12 of the transistor HBT1 is coupled to the control terminal HBN1C of the transistor HBT1, the terminal HBN22 of the transistor HBT2 is coupled to the control terminal HBN2C of the transistor HBT2, and the terminal HBN12 of the transistor HBT1 is coupled to the terminal HBN22 of the transistor HBT2. On the other hand, the electrostatic discharge protection circuit 100-2 in FIG. 2B includes impedance circuits 210 and 220. The impedance circuit 210 is coupled between the control terminal HBN1C and the terminal HBN12 of the transistor HBT1. The impedance circuit 220 is coupled between the control terminal HBN2C and the terminal HBN22 of the transistor HBT2. For the detailed circuit structure of the impedance circuits 210 and 220, reference may be made to the following FIG. 3 and the description of the corresponding embodiment.

The impedance circuits 210 and 220 may provide a bias voltage to conduct the transistor HBT1 and the transistor HBT2 when an electrostatic discharge event occurs, thereby causing the transistor HBT1 and the transistor HBT2 to discharge the electrostatic discharge current. In this embodiment, the sum of the impedance value of the impedance circuit 210 and the impedance value of the impedance circuit 220 is a comprehensive impedance value. The product of the comprehensive impedance value and the breakdown current of the first junction in the transistor HBT1 is greater than or equal to the conduction voltage of the second junction in the transistor HBT1. Referring to FIG. 2B, when the voltage value of the voltage terminal VN1 is greater than the voltage value of the voltage terminal VN2, and the voltage difference between the voltage terminal VN1 and the voltage terminal VN2 is greater than the breakdown voltage of the first junction in the transistor HBT1 (the junction between the terminal HBN11 and the control terminal HBN1C), the electrostatic discharge event occurs. At this time, since the terminal HBN11 of the transistor HBT1 is formed of the low-doped semiconductor material, the breakdown voltage of the first junction of the transistor HBT1 is relatively high, which results in relatively high anti-interference ability. Therefore, the first junction of the transistor HBT1 is not damaged, and generates breakdown current. The breakdown current may flow through the impedance circuit 210 and the impedance circuit 220 along the path direction indicated by the dashed line arrow 215 shown in FIG. 2B. When the product of the comprehensive impedance value of the impedance circuit 210 and the impedance circuit 220 and the breakdown current of the first junction in the transistor HBT1 is greater than the conduction voltage of the second junction (the junction between the terminal HBN12 and the control terminal HBN1C) in the transistor HBT1, the transistor HBT1 may be turned on, and the breakdown current may turn the transistor HBT2 on, forming the electrostatic discharge current discharge path. In this way, the electrostatic discharge current may be directed from the voltage terminal VN1 to the voltage terminal VN2 through the transistor HBT1 and the transistor HBT2. On the other hand, when the voltage value of the voltage terminal VN1 is lower than the voltage value of the voltage terminal VN2, and the voltage difference between the voltage terminal VN1 and the voltage terminal VN2 is greater than the breakdown voltage of the third junction in the transistor HBT2 (the junction between the terminal HBN21 and the control terminal HBN2C), the electrostatic discharge event occurs. At this time, since the terminal HBN21 of the transistor HBT2 is formed of the low-doped semiconductor material, the breakdown voltage of the third junction in the transistor HBT2 is relatively high, which results in relatively high anti-interference ability. Therefore, the third junction of the transistor HBT2 is not damaged, and generates breakdown current. The breakdown current may flow through the impedance circuit 210 along the path direction indicated by the dashed line arrow 225 shown in FIG. 2B. When the product of the comprehensive impedance value of the impedance circuit 210 and the impedance circuit 220 and the breakdown current of the third junction in the transistor HBT2 is greater than the conduction voltage of the fourth junction (the junction between the terminal HBN22 and the control terminal HBN1C) in the transistor HBT2, the transistor HBT2 may be turned on, and the breakdown current may turn the transistor HBT1 on to form an electrostatic discharge current discharge path. In this way, the electrostatic discharge current may be directed from the voltage terminal VN2 to the voltage terminal VN1 through the transistor HBT2 and the transistor HBT1.

Compared to FIG. 2A and FIG. 2B, an electrostatic discharge protection circuit 100-3 in FIG. 2C and an electrostatic discharge protection circuit 100-4 in FIG. 2D use different types of heterojunction bipolar transistors to implement the transistors HBT1 and HBT2. The transistors HBT1 and HBT2 in FIG. 2C and FIG. 2D are both PNP-type heterojunction bipolar transistors. In other words, the coupling relationship of the circuit structures in FIG. 2A and FIG. 2C is the same, and the difference therebetween is merely that the transistors HBT1 and HBT2 are NPN-type or PNP-type heterojunction bipolar transistors. The coupling relationship of the circuit structures in FIG. 2B and FIG. 2D is the same, and the difference therebetween is merely that the transistors HBT1 and HBT2 are NPN-type or PNP-type heterojunction bipolar transistors. In FIG. 2C and FIG. 2D, the semiconductor materials M1 and M3 of the transistors HBT1 and HBT2 are each low-doped P-type semiconductor materials, the semiconductor materials M2 and M4 are each N-type semiconductor materials, and the semiconductor material M5 is a highly-doped P-type semiconductor material.

Compared to FIG. 2A to FIG. 2D, the transistors HBT1 and HBT2 in electrostatic discharge protection circuits 100-5 to 100-8 in FIG. 2E to FIG. 2H are implemented using different types of heterojunction bipolar transistors. For example, FIG. 2E and FIG. 2F use PNP-type and NPN-type transistors to respectively implement the transistors HBT1 and HBT2; FIG. 2G and FIG. 2H use NPN-type and PNP-type transistor to respectively implement the transistors HBT1 and HBT2. In FIG. 2E to FIG. 2G, the terminal HBN11 of the transistor HBT1 is formed of the semiconductor material M1, and the control terminal HBN1C of the transistor HBT1 is formed of the semiconductor material M2. The terminal HBN21 of the transistor HBT2 is formed of the semiconductor material M3, and the control terminal HBN2C of the transistor HBT2 is formed of the semiconductor material M4. The terminal HBN12 of the transistor HBT1 is formed of the semiconductor material M5, and the terminal HBN22 of the transistor HBT2 is formed of the semiconductor material M6. The doping concentration of the semiconductor material M1 forming the terminal HBN11 of the transistor HBT1 is lower than the doping concentration of the semiconductor material M5 forming the terminal HBN12 of the transistor HBT1, and the doping concentration of the semiconductor material M3 of the terminal HBN21 of the transistor HBT2 is lower than the doping concentration of the semiconductor material M6 of the terminal HBN22 of the transistor HBT2. The doping concentration of the semiconductor material M1 is, for example, equal to the doping concentration of the semiconductor material M3. The doping concentration of the semiconductor material M5 is, for example, equal to the doping concentration of the semiconductor material M6.

In FIG. 2E and FIG. 2F, the semiconductor materials M1, M4 and M5 have the same electrical conductivity type, for example, N-type electrical conductivity type or P-type electrical conductivity type. The semiconductor materials M2, M3, and M6 have the same electrical conductivity type, but have different electrical conductivity types from the semiconductor materials M1, M4, and M5. That is to say, as in the embodiments of FIG. 2E and FIG. 2F, the semiconductor materials M1, M4, and M5 are P-type conductive type semiconductor materials, and the semiconductor materials M2, M3, and M6 are N-type conductive type semiconductor materials. On the other hand, in FIG. 2G and FIG. 2H of similar embodiments described later, the semiconductor materials M1, M4, and M5 are N-type conductive type semiconductor materials, while the semiconductor materials M2, M3, and M6 are P-type conductive type semiconductor materials.

The transistors HBT1 and HBT2 in this embodiment are implemented by hetero-bipolar junction transistors. Therefore, the semiconductor material M1 is different from the semiconductor material M5, and the semiconductor material M3 is different from the semiconductor material M6.

In the electrostatic discharge protection circuit 100-5 in FIG. 2E and the electrostatic discharge protection circuit 100-6 in FIG. 2F, the transistor HBT1 is a PNP-type heterojunction bipolar transistor, and the transistor HBT2 is an NPN-type heterojunction bipolar transistor. In detail, the semiconductor material M1 is a low-doped P-type semiconductor material, the semiconductor material M2 is an N-type semiconductor material, and the semiconductor material M3 is a low-doped N-type semiconductor material. The semiconductor material M4 is a P-type semiconductor material, the semiconductor material M5 is a highly-doped P-type semiconductor material, and the semiconductor material M6 is a highly-doped N-type semiconductor material.

In FIG. 2E, the control terminal HBN1C of the transistor HBT1 is coupled to the control terminal HBN2C of the transistor HBT2 through the impedance circuit 210.

In FIG. 2F, the control terminal HBN1C of the transistor HBT1 is coupled to the terminal HBN12 of the transistor HBT1 through the impedance circuit 210. In FIG. 2F, the control terminal HBN2C of the transistor HBT2 is coupled to the terminal HBN22 of the transistor HBT2 through the impedance circuit 220. Furthermore, the terminal HBN12 of the transistor HBT1 is coupled to the terminal HBN22 of the transistor HBT2.

In the electrostatic discharge protection circuit 100-7 in FIG. 2G and the electrostatic discharge protection circuit 100-8 in FIG. 2H, the transistor HBT1 is an NPN-type heterojunction bipolar transistor, and the transistor HBT2 is a PNP-type heterojunction bipolar transistor. In detail, the semiconductor material M1 is a low-doped N-type semiconductor material, the semiconductor material M2 is a P-type semiconductor material, and the semiconductor material M3 is a low-doped P-type semiconductor material. The semiconductor material M4 is an N-type semiconductor material, the semiconductor material M5 is a highly-doped N-type semiconductor material, and the semiconductor material M6 is a highly-doped P-type semiconductor material.

In FIG. 2G, the control terminal HBN1C of the transistor HBT1 is coupled to the control terminal HBN2C of the transistor HBT2 through the impedance circuit 210.

In FIG. 2H, the control terminal HBN1C of the transistor HBT1 is coupled to the terminal HBN12 of the transistor HBT1 through the impedance circuit 210. In FIG. 2H, the control terminal HBN2C of the transistor HBT2 is coupled to the terminal HBN22 of the transistor HBT2 through the impedance circuit 220. Furthermore, the terminal HBN12 of the transistor HBT1 is coupled to the terminal HBN22 of the transistor HBT2.

FIG. 3 is a schematic circuit diagram of the impedance circuit 210 according to various embodiments of the disclosure. The impedance circuit 210 and the impedance circuit 220 in each embodiment of the disclosure may be implemented through impedance circuits 211-1 to 211-9 in FIG. 3 or other circuit structures. The impedance circuits 210, 220, 210-1 to 210-M (indicating being arranged from 210-1, 210-2, 210-3, and all the way to 210-M), and 220-1 to 220-N (indicating being arranged from 220-1, 220-2, 220-3, and all the way to 220-N) in various embodiments of the disclosure may be the same circuit structure, or may be selected from the impedance circuits 211-1 to 211-9 in FIG. 3 for implementation.

The various impedance circuits 211-1 to 211-9 in FIG. 3 may include one or a combination of a resistor R1 (the impedance circuit 211-1), a capacitor C1 (the impedance circuit 211-2), an inductor L1 (the impedance circuit 211-3), at least one diode (for example, diodes D1 and D2), at least one first field-effect transistor (for example, field-effect transistors FET1 and FET2), and at least one first metal-oxide-semiconductor field-effect transistor (MOSFET) (for example, field-effect transistors M1 and M2). The impedance circuits 211-4 and 211-5 respectively include one or more diodes D1 and D2 connected in series. In other words, the impedance circuits 211-4 and 211-5 are formed by stacking multiple diodes D1 and D2.

The impedance circuits 211-6 and 211-7 are respectively formed by multiple field-effect transistors FET1 or FET2 connected in series, and the control terminal of each field-effect transistor FET1 or FET2 is coupled to the source terminal or drain terminal thereof. The field-effect transistors FET1 or FET2 may be N-type or P-type field-effect transistors. In other words, the impedance circuits 211-6 and 211-7 are respectively formed by stacking multiple field-effect transistors FET1 and FET2.

The impedance circuits 211-8 and 211-9 are respectively formed by multiple field-effect transistors M1 or M2 connected in series, and the control terminal of each field-effect transistor M1 or M2 is coupled to the source terminal or drain terminal thereof. The field-effect transistor M1 or M2 may be N-type or P-type field-effect transistors. In other words, the impedance circuits 211-8 and 211-9 are respectively formed by stacking multiple field-effect transistors M1 and M2.

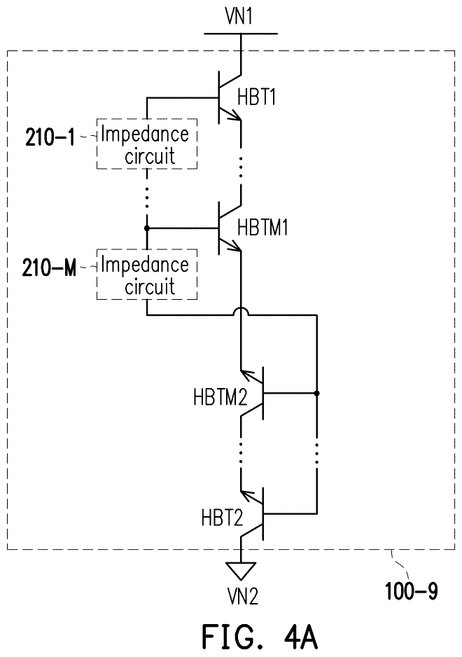

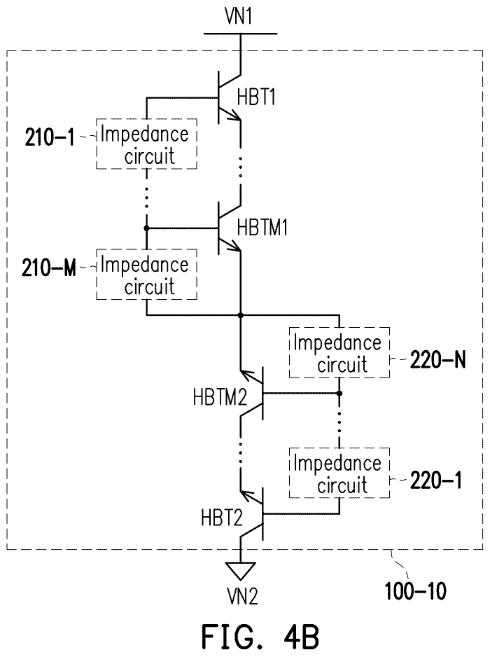

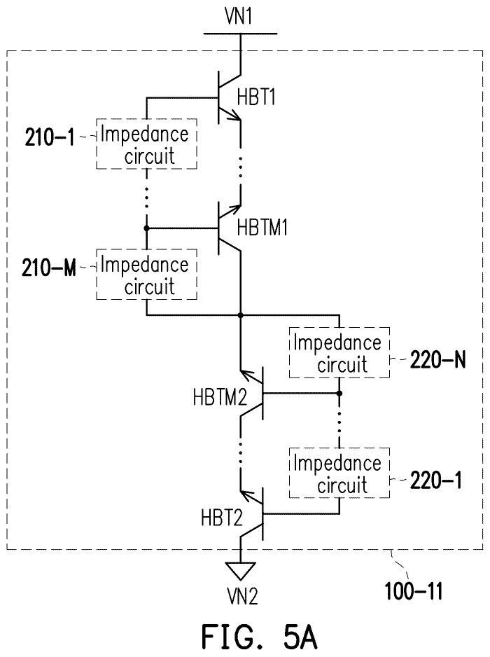

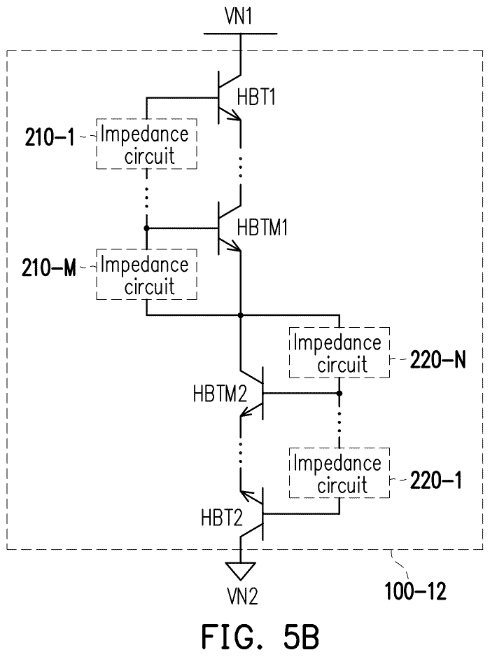

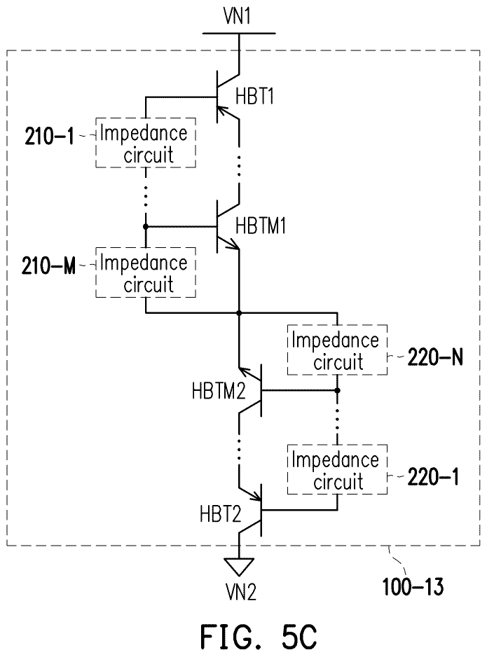

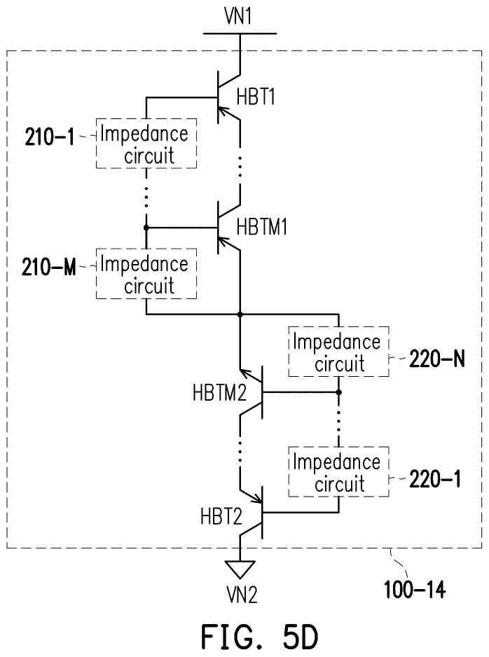

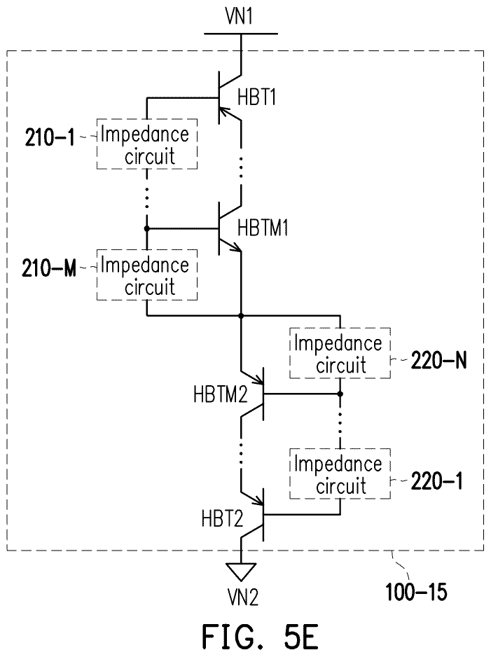

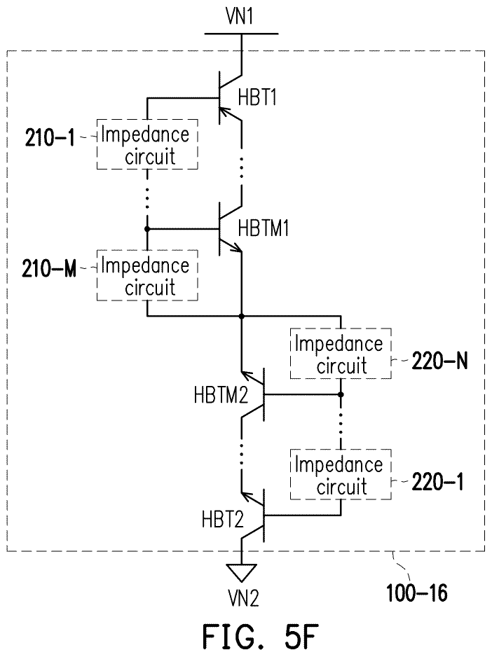

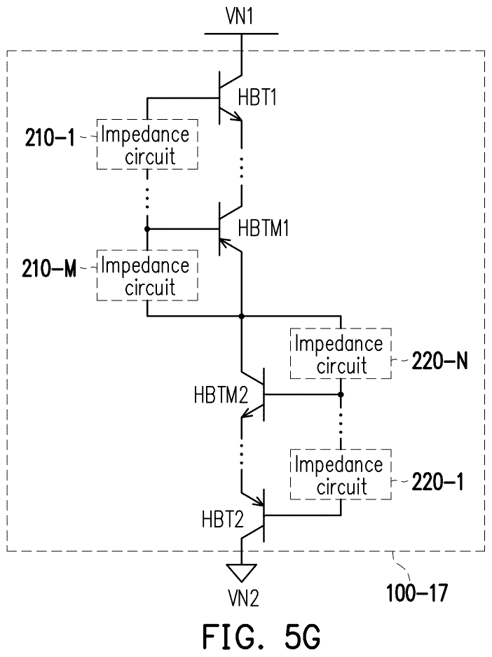

In FIG. 2A to FIG. 2H, the terminal HBN12 of the transistor HBT1 is directly coupled to the terminal HBN22 of the transistor HBT2, persons implementing this embodiment may make the terminal HBN12 of the transistor HBT1 be coupled to the terminal HBN22 of the transistor HBT2 through one or more intermediate transistors, as shown in FIG. 4A to FIG. 4B and FIG. 5A to FIG. 5G.

FIG. 4A to FIG. 4B are respectively schematic circuit diagrams of electrostatic discharge protection circuits 100-9 to 100-10 according to the ninth embodiment to the tenth embodiment of the disclosure. The transistors HBT1 and HBT2 and the transistors HBTM1 and HBTM2 in FIG. 4A to FIG. 4B are all implemented based on NPN-type heterojunction bipolar transistors. The terminal (for example, emitter terminal) of the transistor HBT1 is coupled to the terminal (for example, emitter terminal) of the transistor HBT2 through one or more intermediate transistors (such as one or more transistors HBTM1 and HBTM2 in FIG. 4A to FIG. 4B and FIG. 5A to FIG. 5G). In FIG. 4A, the impedance circuit 210-1 to 210-M (indicating being arranged from 210-1, 210-2, 210-3, and all the way to 210-M) may be disposed between the control terminal of the transistor HBT1 and the control terminal of a next-level transistor (for example, the transistor HBTM1). It is worth noting that, in the modified embodiment of FIG. 4A, the impedance circuit may only use the impedance circuit 210-M closest to the middle (the impedance circuit 210-M is simultaneously coupled to the control terminal of the transistor HBTM1 and the control terminal of the transistor HBTM2), and the impedance circuits 210-1, 210-2, 210-3 . . . 210-(M−1) may be omitted. In FIG. 4B, the additional impedance circuits 220-1 to 220-N (indicating being arranged from 220-1, 220-2, 220-3, and all the way to 220-N) may be disposed between the control terminal of the transistor HBT2 and the control terminal of a next-level transistor (for example, the transistor HBTM2). It is worth noting that, in the modified embodiment of FIG. 4B, the impedance circuit may only use the impedance circuit 210-M and the impedance circuit 220-N closest to the middle (the impedance circuit 210-M is directly coupled to the impedance circuit 220-N), and the impedance circuits 210-1, 210-2, 210-3 . . . 210-(M−1) and the impedance circuits 220-1, 220-2, 220-3 . . . 220-(N−1) may be omitted.

The control terminals of the transistors HBTM1 and HBTM2 closest to the middle may not be coupled to the emitter terminals thereof (as shown in FIG. 4A), alternatively, the control terminals of the transistors HBTM1 and HBTM2 closest to the middle may be coupled to the emitter terminals thereof (as shown in FIG. 4B). The transistors HBT1 and HBT2 couple the base-collector junction with high breakdown voltage to the voltage terminals VN1 and VN2.

On the other hand, the series connection methods of junctions between respective transistors (for example, the transistors HBTM1 and HBTM2) between the transistors HBT1 and HBT2 are not limited to the embodiments of the disclosure. FIG. 5A to FIG. 5G are respectively schematic circuit diagrams of electrostatic discharge protection circuits 100-11 to 100-17 according to the eleventh embodiment to the seventeenth embodiment of the disclosure. The difference between FIG. 5A and FIG. 4B is that, the coupling method between the emitter terminal and the collector terminal of the transistor HBTM1 closest to the middle in the electrostatic discharge protection circuit 100-11 in FIG. 5A is different from the transistor HBTM1 of the electrostatic discharge protection circuit 100-10 in FIG. 4B.

The difference between FIG. 5B and FIG. 4B is that, the coupling method between the emitter terminal and the collector terminal of the transistor HBTM2 closest to the middle in the electrostatic discharge protection circuit 100-12 in FIG. 5B is different from the transistor HBTM2 of the electrostatic discharge protection circuit 100-10 in FIG. 4B.

In FIG. 5C to FIG. 5E, the transistors HBT1 and HBT2 of the electrostatic discharge protection circuits 100-13 to 100-15 are PNP-type heterojunction bipolar transistors, which are different from the electrostatic discharge protection circuit 100-10 in FIG. 4B. Moreover, the transistors HBTM1 and HBTM2 of the electrostatic discharge protection circuit 100-13 in FIG. 5C are NPN-type heterojunction bipolar transistors.

The transistor HBTM1 of the electrostatic discharge protection circuit 100-14 in FIG. 5D is a PNP-type heterojunction bipolar transistor, and the transistor HBTM2 is an NPN-type heterojunction bipolar transistor.

The transistor HBTM1 of the electrostatic discharge protection circuit 100-15 in FIG. 5E is an NPN-type heterojunction bipolar transistor, and the transistor HBTM2 is a PNP-type heterojunction bipolar transistor.

The transistor HBT1 of the electrostatic discharge protection circuit 100-16 in FIG. 5F is a PNP-type heterojunction bipolar transistor, and the transistors HBTM1, HBTM2, and HBT2 are NPN-type heterojunction bipolar transistors.

The transistors HBT1 and HBTM2 of the electrostatic discharge protection circuit 100-17 in FIG. 5G are NPN-type heterojunction bipolar transistors, and the transistors HBTM1 and HBT2 are PNP-type heterojunction bipolar transistors.

In summary, through a specific circuit structure, the electrostatic discharge protection circuit of the embodiments of the disclosure utilizes the base-collector junction of the hetero-bipolar junction transistor to be coupled to the corresponding voltage terminal, instead of utilizing the base-emitter junction with a lower breakdown voltage to be coupled to the voltage terminal. Therefore, when a voltage electrostatic discharge event occurs, the electrostatic discharge protection circuit can increase the anti-interference ability based on the base-collector junction with a relatively high breakdown voltage.

What is claimed is:

1. An electrostatic discharge protection circuit coupled between a first voltage terminal and a second voltage terminal, wherein the electrostatic discharge protection circuit comprises:
a first bipolar junction transistor having a first terminal, a second terminal, and a control terminal, wherein the first terminal of the first bipolar junction transistor is coupled to the first voltage terminal; and
a second bipolar junction transistor having a first terminal, a second terminal, and a control terminal, wherein the second terminal of the second bipolar junction transistor is coupled to the second terminal of the first bipolar junction transistor, the first terminal of the second bipolar junction transistor is coupled to the second voltage terminal, and the control terminal of the first bipolar junction transistor is coupled to the control terminal of the second bipolar junction transistor,
wherein a first breakdown voltage of a first junction between the first terminal and the control terminal of the first bipolar junction transistor is greater than a second breakdown voltage of a second junction between the second terminal and the control terminal of the first bipolar junction transistor, and
a third breakdown voltage of a third junction between the first terminal and the control terminal of the second bipolar junction transistor is greater than a fourth breakdown voltage of a fourth junction between the second terminal and the control terminal of the second bipolar junction transistor.

2. The electrostatic discharge protection circuit as claimed in claim 1, wherein the first terminal of the first bipolar junction transistor is formed of a first type semiconductor material, and the control terminal of the first bipolar junction transistor is formed of a second type semiconductor material,
the first terminal of the second bipolar junction transistor is formed of a third type semiconductor material, and the control terminal of the second bipolar junction transistor is formed of a fourth type semiconductor material,
the second terminal of the first bipolar junction transistor and the second terminal of the second bipolar junction transistor are both formed of a fifth-type semiconductor material,
wherein the first type semiconductor material, the third type semiconductor material, and the fifth type semiconductor material have same conductive type, the fifth type semiconductor material is different from the first type semiconductor material or the third type semiconductor material, and the second type semiconductor material and the fourth type semiconductor material have same conductive type.

3. The electrostatic discharge protection circuit as claimed in claim 2, wherein the first type semiconductor material and the third type semiconductor material are each low-doped N-type semiconductor materials, the second type semiconductor material and the fourth type semiconductor material are each P-type semiconductor materials, and the fifth type semiconductor material is a highly-doped N-type semiconductor material.

4. The electrostatic discharge protection circuit as claimed in claim 2, wherein the first type semiconductor material and the third type semiconductor material are each low-doped P-type semiconductor materials, the second type semiconductor material and the fourth type semiconductor material are each N-type semiconductor materials, and the fifth type semiconductor material is a highly-doped P-type semiconductor material.

5. The electrostatic discharge protection circuit as claimed in claim 1, wherein the first terminal of the first bipolar junction transistor is formed of a first type semiconductor material, and the control terminal of the first bipolar junction transistor is formed of a second type semiconductor material,
the first terminal of the second bipolar junction transistor is formed of a third type semiconductor material, and the control terminal of the second bipolar junction transistor is formed of a fourth type semiconductor material,
the second terminal of the first bipolar junction transistor is formed of a fifth-type semiconductor material, and the second terminal of the second bipolar junction transistor is formed of a sixth-type semiconductor material,
wherein the first type semiconductor material, the fourth type semiconductor material, and the fifth type semiconductor material have same conductive type, and the second type semiconductor material, the third type semiconductor material, and the sixth type semiconductor material have same conductive type.

6. The electrostatic discharge protection circuit as claimed in claim 5, wherein
the first type semiconductor material is a low-doped P-type semiconductor material, the second type semiconductor material is an N-type semiconductor material, the third type semiconductor material is a low-doped N-type semiconductor material, the fourth type semiconductor material is a P-type semiconductor material, the fifth-type semiconductor material is a highly-doped P-type semiconductor material, and the sixth-type semiconductor material is a highly-doped N-type semiconductor material;
alternatively, the first type semiconductor material is a low-doped N-type semiconductor material, the second type semiconductor material is a P-type semiconductor material, the third type semiconductor material is a low-doped P-type semiconductor material, the fourth type semiconductor material is an N-type semiconductor material, the fifth-type semiconductor material is a highly-doped N-type semiconductor material, and the sixth-type semiconductor material is a highly-doped P-type semiconductor material.

7. The electrostatic discharge protection circuit as claimed in claim 1, wherein the first breakdown voltage is equal to the third breakdown voltage, and the second breakdown voltage is equal to the fourth breakdown voltage.

8. The electrostatic discharge protection circuit as claimed in claim 1, wherein the first terminal of the first bipolar junction transistor is a first collector, the second terminal of the first bipolar junction transistor is a first emitter, the first terminal of the second bipolar junction transistor is a second collector, the second terminal of the second bipolar junction transistor is a second emitter, and the first emitter is coupled to the second emitter.

9. The electrostatic discharge protection circuit as claimed in claim 1, wherein the second terminal of the first bipolar junction transistor is coupled to the second terminal of the second bipolar junction transistor through one or more intermediate transistors.

10. The electrostatic discharge protection circuit as claimed in claim 1, further comprising a first impedance circuit and a second impedance circuit, wherein
the first impedance circuit is coupled between the control terminal and the second terminal of the first bipolar junction transistor,
the second impedance circuit is coupled between the control terminal and the second terminal of the second bipolar junction transistor, and the second terminal of the first bipolar junction transistor is coupled to the second terminal of the second bipolar junction transistor.

11. The electrostatic discharge protection circuit as claimed in claim 10, wherein the first impedance circuit comprises one or a combination of a first resistor, a first capacitor, a first inductor, a first diode, at least one first field-effect transistor, and at least one first field-effect transistor, and
the second impedance circuit comprises one or a combination of a second resistor, a second capacitor, a second inductor, a second diode, at least one second field-effect transistor, and at least one second field-effect transistor.

12. The electrostatic discharge protection circuit as claimed in claim 10, wherein a sum of an impedance value of the first impedance circuit and an impedance value of the second impedance circuit is a comprehensive impedance value, in response to a voltage value of the first voltage terminal being greater than a voltage value of the second voltage terminal and an electrostatic discharge event occurring, a product of the comprehensive impedance value and a first breakdown current of the first junction of the first bipolar junction transistor is greater than or equal to a first conduction voltage of the second junction of the first bipolar junction transistor, and in response to a voltage value of the second voltage terminal being greater than a voltage value of the first voltage terminal and the electrostatic discharge event occurring, a product of the comprehensive impedance value and a third breakdown current of the third junction of the second bipolar junction transistor is greater than or equal to a second conduction voltage of the fourth junction of the second bipolar junction transistor.

13. The electrostatic discharge protection circuit as claimed in claim 1, further comprising a first impedance circuit, wherein the first impedance circuit is coupled between the control terminal of the first bipolar junction transistor and the control terminal of the second bipolar junction transistor.

14. The electrostatic discharge protection circuit as claimed in claim 13, wherein the first impedance circuit comprises one or a combination of a resistor, a capacitor, an inductor, a diode, a field-effect transistor, and a field-effect transistor.

15. The electrostatic discharge protection circuit as claimed in claim 13, wherein in response to a voltage value of the first voltage terminal being greater than a voltage value of the second voltage terminal and an electrostatic discharge event occurring, a product of the impedance value of the first impedance circuit and a first breakdown current of the first junction of the first bipolar junction transistor is greater than or equal to a first conduction voltage of the second junction of the first bipolar junction transistor, and in response to a voltage value of the second voltage terminal being greater than a voltage value of the first voltage terminal and the electrostatic discharge event occurring, a product of the impedance value of the first impedance circuit and a third breakdown current of the third junction of the second bipolar junction transistor is greater than or equal to a second conduction voltage of the fourth junction of the second bipolar junction transistor.

16. The electrostatic discharge protection circuit as claimed in claim 1, wherein the first bipolar junction transistor and the second bipolar junction transistor are both heterojunction bipolar transistors.

17. The electrostatic discharge protection circuit as claimed in claim 1, wherein the first voltage terminal is a voltage input terminal, and the second voltage terminal is a reference voltage terminal.

18. The electrostatic discharge protection circuit as claimed in claim 1, wherein the electrostatic discharge protection circuit is used in a high-power radio frequency signal processing circuit.

19. An electrostatic discharge protection circuit coupled between a first voltage terminal and a second voltage terminal, wherein the electrostatic discharge protection circuit comprises:
a first bipolar junction transistor having a first terminal, a second terminal, and a control terminal, wherein the first terminal of the first bipolar junction transistor is coupled to the first voltage terminal; and
a second bipolar junction transistor having a first terminal, a second terminal, and a control terminal, wherein the second terminal of the second bipolar junction transistor is coupled to the second terminal of the first bipolar junction transistor, the first terminal of the second bipolar junction transistor is coupled to the second voltage terminal, and the control terminal of the first bipolar junction transistor is coupled to the control terminal of the second bipolar junction transistor,
wherein a first doping concentration of a semiconductor material forming the first terminal of the first bipolar junction transistor is lower than a second doping concentration of a semiconductor material forming the second terminal of the first bipolar junction transistor, and a third doping concentration of a semiconductor material forming the first terminal of the second bipolar junction transistor is lower than a fourth doping concentration of the semiconductor material forming the second terminal of the second bipolar junction transistor.

20. The electrostatic discharge protection circuit as claimed in claim 19, wherein the first doping concentration is equal to the third doping concentration, and the second doping concentration is equal to the fourth doping concentration.
